(19) United States
(12) Patent Application Publication
(10) Pub. No.: US 2014/0379284 A1
(43) Pub. Date: Dec. 25, 2014

(54) SYSTEM AND METHOD FOR CALCULATING TOTAL AVAILABLE ENERGY FROM VEHICLE BATTERY

(71) Applicants: Kia Motors Corporation, Seoul (KR); Hyundai Motor Company, Seoul (KR)

(72) Inventors: Sang Jin Heo, Ulsan (KR); Seon Young Park, Paju (KR); Eui Sun Hong, Cheonan (KR); Byung Soon Min, Seongnam (KR); Young Chan Byun, Seoul (KR)

(73) Assignees: KIA MOTORS CORPORATION, Seoul (KR); HYUNDAI MOTOR COMPANY, Seoul (KR)

(21) Appl. No.: 14/070,901

(22) Filed: Nov. 4, 2013

(30) Foreign Application Priority Data
Jun. 21, 2013 (KR) 10-2013-0071399

(51) Int. Cl. G01R 31/36

(52) U.S. Cl. CPC G01R 31/362
USPC 702/63

(57) ABSTRACT

A system and method for calculating available energy of a battery is provided and the system includes a controller configured to receive State-Of-Charge (SOC) of the battery as an input and output an Open-Circuit Voltage (OCV) of the battery. In addition, a value of available energy is stored in a memory and the controller obtains a value of charged and discharged energy and a value of heat loss energy from an OCV of the battery, an output voltage of a battery system, and an output current of the battery system. The value of the obtained charged and discharged energy are added to the value of the available energy which has been previously stored and the value of the heat loss energy is subtracted to calculate a value of new available energy.

### CROSS REFERENCE TO RELATED APPLICATION

This application claims under 35 U.S.C. §119(a) priority to Korean Patent Application No. 10-2013-0071399 filed on Jun. 21, 2013, the entire contents of which are incorporated herein by reference.

### BACKGROUND

1. Field of the Invention

The present invention relates to a system and a method for accurately calculating total available energy of a vehicle battery without errors by taking into account the influence of disturbance.

2. Description of the Related Art

For a motor-driven vehicle whose propulsion is provided by a motor which operates on a battery, a calculation of a maximum driving range may be obtained using a calculation of accurate available energy of a battery. In particular, conventional methods are suggested in which currents are integrated and an Open-Circuit Voltage (OCV) of a battery is calculated to correct State-Of-Charge (SOC), and a maximum driving range is calculated from the corrected SOC. Using this method the SOC is susceptible to change by disturbances such as temperature or deterioration causing available energy, as a final estimation result, to be inaccurate. Accordingly, it is necessary to establish a calculation method of accurately calculating the available energy of a battery without being influenced by a disturbance. The calculation method may directly calculate the available energy, rather than indirectly estimate the available energy from the SOC.

The foregoing is intended merely to aid in the understanding of the background of the present invention, and is not intended to mean that the present invention falls within the purview of the related art that is already known to those skilled in the art.

### SUMMARY

Accordingly, the present invention provides a system and method for accurately calculating available energy of vehicle battery without errors (e.g., minimal errors) by taking into account the influence of disturbance.

In particular, according to one aspect of the present invention, there is provided a system for calculating available energy of a vehicle battery, that includes a data unit that receives State-Of-Charge (SOC) as an input and that outputs an Open-Circuit Voltage (OCV) of the battery, a storage unit that stores a value of available energy, and a calculation unit that calculates a value of charged and discharged energy and a value of heat loss energy from the OCV of the battery, an output voltage of a battery system, and an output current of the battery system, and adds the value of the obtained charged and discharged energy to the value of the available energy which is previously stored in the storage unit, and subtracts the value of the heat loss energy, thereby calculating a value of new available energy.

The calculation unit may be configured to obtain the value of the charged and discharged energy from the output voltage and the output current of the battery system. In addition, the calculation unit may be configured to obtain the value of the heat loss energy from a difference between the OCV of the battery and the output voltage of the battery system and the output current of the battery system. The calculation unit may be configured to obtain the value of the new available energy based on the following expression:

New_available_energy=∫i•Vₜdt−∫|i•(Vₜ−Vₑ)|dt+previously_stored_available_energy

Where i is an output current of a battery system, Vₜ is an output voltage of a battery system, and Vₑ is the open-circuit voltage of a battery.

The storage unit may be configured to replace the value of the available energy which is stored with the value of the new available energy. The calculation unit may be configured to adopt the value of the available energy which is stored in the storage unit as the value of the new available energy when a vehicle is in no-load conditions. In addition, the calculation unit may be configured to calculate a maximum driving range by multiplying the value of the new available energy by an electric ratio (e.g., distance-to-power ratio).

A method for calculating available energy of a vehicle battery may include a charged and discharged energy value obtaining step that obtains a value of charged and discharged energy from an output voltage and an output current of a battery system, a energy-loss value obtaining step that obtains a value of heat loss energy from a difference between an Open-Circuit Voltage (OCV) of the battery and the output voltage of the battery system, and the output current of the battery system, and a final available energy value obtaining step that obtains a value of the available energy of the battery from the value of the charged and discharged energy and the value of the heat loss energy.

The method for calculating available energy of a battery may use the value of the charged and discharged energy and the value of the heat loss energy using the OCV of the battery and the output voltage and output current of the battery system, and subtract the value of the heat loss energy from the value of the charged and discharged energy, thereby calculating the value of the available energy of the battery.

According to the system and method for calculating available energy of a vehicle battery which is described above, when calculating the value of the available energy the use of a battery characteristic table including temperature and SOC may be omitted. Furthermore, a logic processor that implements the system and the method, according to the present invention, may be constructed and it may be possible to eliminate time for conducting experiments to create a battery characteristic tables, including dynamic and thermal characteristics of a battery, and the logic processor, which is not susceptible to disturbances such as temperature or deterioration, may be easily obtained.

### BRIEF DESCRIPTION OF THE DRAWINGS

The above and other features of the present invention will now be described in detail with reference to exemplary embodiments thereof illustrated the accompanying drawings which are given hereinbelow by way of illustration only, and thus are not limitative of the present invention, and wherein:

FIG. 1 is an exemplary diagram illustrating a system for calculating available energy of a battery in a vehicle according to one exemplary embodiment of the present invention; and

FIG. 2 is an exemplary flowchart illustrating a method of calculating available energy of a battery in a vehicle according to another exemplary embodiment of the present invention.

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, combustion, plug-in hybrid electric vehicles, hydrogen-powered vehicles and other alternative fuel vehicles (e.g. fuels derived from resources other than petroleum).

Although exemplary embodiment is described as using a plurality of units to perform the exemplary process, it is understood that the exemplary processes may also be performed by one or plurality of modules. Additionally, it is understood that the term controller/control unit refers to a hardware device that includes a memory and a processor. The memory is configured to store the modules and the processor is specifically configured to execute said modules to perform one or more processes which are described further below.

Furthermore, control logic of the present invention may be embodied as non-transitory computer readable media on a computer readable medium containing executable program instructions executed by a processor, controller/control unit or the like. Examples of the computer readable mediums include, but are not limited to, ROM, RAM, compact disc (CD)-ROMs, magnetic tapes, floppy disks, flash drives, smart cards and optical data storage devices. The computer readable recording medium can also be distributed in network coupled computer systems so that the computer readable media is stored and executed in a distributed fashion, e.g., by a telematics server or a Controller Area Network (CAN).

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Hereinbelow, exemplary embodiments of the present invention will be described in detail with reference to the accompanying drawings.

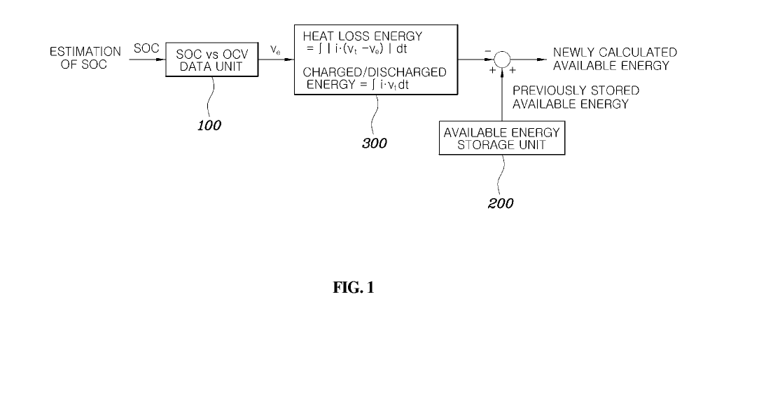

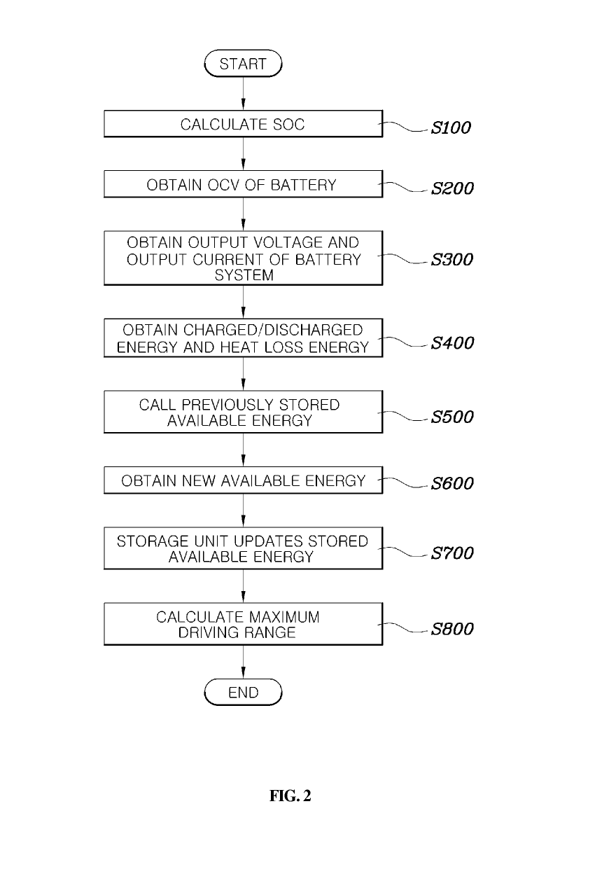

FIG. 1 is an exemplary diagram illustrating a system for calculating available energy of a vehicle battery according to one exemplary embodiment of the present invention, and FIG. 2 is an exemplary flowchart illustrating a method of calculating available energy of a vehicle battery according to another exemplary embodiment of the present invention.

The method for calculating available energy of a vehicle battery according to the exemplary embodiment may include calculating, by a controller, a value of the available energy of the battery by obtaining a value of charged and discharged energy and a value of heat loss energy from an Open-Circuit Voltage (OCV) of the battery, an output voltage of a battery system, and an output current of the battery system, and subtracting a value of the heat loss energy from the charged and discharged energy.

Specifically, the system for calculating available energy of a vehicle battery may include a plurality of unit executed by a controller. The plurality of units may include a data unit 100 configured to receive SOC of the battery as an input and configured to output the OCV of the battery, a storage unit 200 configured to store a value of the available energy, and a calculation unit 300 configured to obtain a value of changed energy and a value of heat loss energy from the OCV of the battery, an output voltage of a battery system, and an output current of the battery system, and adds the value of the calculated charged/discharged energy to a value of the available energy which has been previously stored, and subtracts the value of the heat loss energy from the value of the charged/discharged energy.

The data unit 100 may include a table or a function in which the SOC of the battery operates as an input and the OCV of the battery operates as an output. Accordingly, the OCV of the battery may be obtained using the currently estimated SOC as an input. In addition, the storage unit may be configured to store the value of the available energy of the battery which is previously calculated. When a value of new available energy is obtained, the storage unit may be configured to update the value of the available energy.

The calculation unit 300 may be configured to obtain the value of the charged and discharged energy and the value of the heat loss energy from the OCV of the battery, the output voltage of the battery system, and the output current of the battery system, add the value of the obtained charged and discharged energy obtained to the value of the available energy which has been previously stored, and subtract the value of the heat loss energy to calculate the value of new available energy. Specifically, the calculation unit may be configured to obtain the value of the charged and discharged energy from the output voltage and output current of the battery system.

In addition, the calculation unit may be configured to calculate the heat loss energy from a difference between the OCV of the battery and the output voltage of the battery system and the output current of the battery system. In other words, the calculation unit 300 may first be configured to obtain the value of the charged and discharged energy from the output voltage and output current of the battery system, then calculate the heat loss energy from the difference between the OCV of the battery and the output voltage of the battery system and the output current of the battery system, and finally obtain the value of the available energy from the value of the charged and discharged energy and the value of the heat loss energy.

Specifically, the calculation unit 300 may be configured to calculate the value of the available energy as illustrated in the following expression.

New_available_energy=∫i•Vₜdt−∫|i•(Vₜ−Vₑ)|dt+previously_stored_available_energy Expression 1

Where i is an output current of a battery system, Vₜ is an output voltage of a battery system, and Vₑ is the OCV of a battery.

The storage unit 200 may be configured to update the previously stored available energy with the newly calculated available energy. Accordingly, the newly calculated available energy may be calculated by setting the previously stored available energy as an initial value, adding the newly charged and discharged energy to the previously storage available energy, and subtracting the heat loss energy. In this way, the value of the new available energy may be obtained in real time.

When a vehicle is in no-load conditions, the calculation unit 300 may be configured to determine the previously stored available energy as new available energy and the calculation unit 300 may be configured to calculate a maximum driving range by multiplying the new available energy by an electric ratio (e.g., distance to power ratio). The calculated maximum driving range may be expressed in various forms. The electric ratio is a value of the ratio of distance to power and may be expressed in Km/Kwh units. The electric ratio may be obtained by weighing a past electric ratio, a current electric ratio, and a current electric ratio for a predetermined section. The maximum driving range may be predicted by multiplying the electric ratio by the available energy.

FIG. 2 is an exemplary flowchart illustrating the method for calculating available energy of a vehicle battery according to another exemplary embodiment. The method may include a charged and discharged energy value obtaining step (Step S400) that obtains, by a controller, a value of charged and discharged energy from an output voltage and an output current of a battery system, a loss value obtaining step (Step S400) that calculates, by the controller, a value of heat loss energy from a difference between an OCV of the battery and the output voltage of the battery system, and the output current of the battery system, and a final energy value obtaining step (Step S600) that calculates, by the controller, a value of available energy of the battery from the value of the charged and discharged energy and the value of the heat loss energy.

In other words, SOC may be calculated first (Step S100), and the OCV of the battery may then be calculated using the SOC (Step S200). After that, the output voltage and the output current of the battery system may be obtained, by the controller, (Step S300) which may be calculated values, detected values, or set values. Subsequently, the values of the charged and discharged energy and the heat loss energy may be obtained, by the controller, (Step S400). Subsequently, the available energy which had been previously stored may be called out, by the controller, (Step S500) and the value of the charged and discharged energy may be added, by the controller, and value of the heat loss energy may be subtracted, by the controller, from the value of the available energy which has been called out. As a result, a value of new available energy may be calculated by the controller (Step S600). The value of the new available energy may be stored, by the controller, in the storage unit to update the value of the available energy which has been stored (Step S700), and then a maximum driving range may be calculated and displayed by the controller (Step S800).

According to the system and method for calculating available energy of a battery described above, when calculating the available energy the use of a battery characteristic table, which includes variables such as temperature and SOC, may be omitted. Furthermore, a logic processor that implements the system and method according to the present invention, may be constructed and it may be possible to eliminate time for conducting experiments to create a battery characteristic table, including dynamic and thermal characteristics of a battery, and the logic processor, which is not susceptible to disturbances such as temperature or deterioration, may be easily obtained.

Although an exemplary embodiment of the present invention has been described for illustrative purposes, those skilled in the art will appreciate that various modifications, additions and substitutions are possible without departing from the scope and spirit of the invention as disclosed in the accompanying claims.

What is claimed is:

1. A system for calculating available energy of a battery, comprising:
a controller includes a memory and a processor, the memory configured to store program instructions and the processor configured to execute the program instructions, the program instructions when executed configured to:
receive State-Of-Charge (SOC) of the battery as an input and output an Open-Circuit Voltage (OCV) of the battery;
store a value of available energy in the memory; and
obtain a value of charged and discharged energy and a value of heat loss energy from the OCV of the battery, an output voltage of a battery system, and an output current of the battery system;
add the value of the obtained charged and discharged energy to the value of the available energy which has been previously stored; and
subtract the value of the heat loss energy to calculate a value of new available energy.

2. The system according to claim 1, wherein the controller is further configured to obtain the value of the charged and discharged energy using the output voltage and output current of the battery system.

3. The system according to claim 1, wherein the controller is further configured to calculate the value of the heat loss energy using a difference between the OCV of the battery and the output voltage of the battery system, and the output current of the battery system.

4. The system according to claim 1, wherein the controller is further configured to calculate the value of the new available energy using the following expression:
New_available_energy=∫i•Vₜdt−∫|i•(Vₜ−Vₑ)|dt+previously_stored_available_energy
wherein i is an output current of a battery system, Vₜ is an output voltage of a battery system, and Vₑ is the OCV of a battery.

5. The system according to claim 1, wherein the controller is further configured to update the value of the available energy which has been previously stored to the value of the new available energy.

6. The system according to claim 1, wherein when the vehicle is in no-load conditions, the controller is configured to use the value of the available energy which has been previously stored as the value of the new available energy.

7. The system according to claim 1, wherein the controller is further configured to calculate a maximum driving range by multiplying the value of the new available energy, which is calculated by an electric ratio.

8. A method for calculating available energy of a battery in a vehicle, the method comprising:
obtaining, by a controller, a value of charged and discharged energy from an output voltage and an output current of a battery system;
calculating, by the controller, a value of heat loss energy from a difference between an Open-Circuit Voltage (OCV) of the battery and the output voltage of the battery system, and the output current of the battery system; and
calculating, by the controller, a value of the available energy of the battery from the value of the charged and discharged energy and the value of the heat loss energy.

9. The method of claim 8, further comprising:
calculating, by the controller, the value of new available energy using the following expression:
New_available_energy=∫i•Vₜdt−∫|i•(Vₜ−Vₑ)|dt+previously_stored_available_energy
wherein i is an output current of a battery system, Vₜ is an output voltage of a battery system, and Vₑ is the OCV of a battery.

10. The method of claim 8, further comprising:
updating, by the controller, the value of the available energy which has been previously stored to the value of the new available energy.

11. The method of claim 8, further comprising:
using, by the controller, the available energy which has been previously stored as the value of the new available energy when the vehicle is in no-load conditions.

12. The method of claim 8, further comprising:
calculating, by the controller, a maximum driving range by multiplying the value of the new available energy which is calculated by an electric ratio.

13. A method for calculating available energy of a battery in a vehicle, the method including:
obtaining, by a controller, a value of the available energy by obtaining a value of charged and discharged energy and a value of heat loss energy from an Open-Circuit Voltage (OCV) of the battery, an output voltage of a battery system, and an output current of the battery system; and
subtracting, by the controller, the value of the heat loss energy from the value of the charged and discharged energy.

14. A non-transitory computer readable medium containing program instructions executed by a controller, the computer readable medium comprising:
program instructions that obtain a value of charged and discharged energy from an output voltage and an output current of a battery system;
program instructions that calculate a value of heat loss energy from a difference between an Open-Circuit Voltage (OCV) of the battery and the output voltage of the battery system, and the output current of the battery system; and
program instructions that calculate a value of the available energy of the battery from the value of the charged and discharged energy and the value of the heat loss energy.

15. The non-transitory computer readable medium of claim 14, further comprising:
program instructions that calculate the value of new available energy using the following expression:
New_available_energy=∫i•Vₜdt−∫|i•(Vₜ−Vₑ)|dt+previously_stored_available_energy
wherein i is an output current of a battery system, Vₜ is an output voltage of a battery system, and Vₑ is the OCV of a battery.

16. The non-transitory computer readable medium of claim 14, further comprising:
program instructions that update the value of the available energy which has been previously stored to the value of the new available energy.

17. The non-transitory computer readable medium of claim 14, further comprising:
program instructions that use the available energy which has been previously stored as the value of the new available energy when the vehicle is in no-load conditions.

18. The non-transitory computer readable medium of claim 14, further comprising:
program instructions that calculate a maximum driving range by multiplying the value of the new available energy, which is calculated by an electric ratio.
